(19) United States
(12) Patent Application Publication
(10) Pub. No.: US 2025/0085627 A1
(43) Pub. Date: Mar. 13, 2025

(54) ORGANOTIN PHOTORESIST COMPOSITIONS HAVING FLUORIDE GENERATOR COMPOUNDS, FLUORINATED ORGANOTIN COATINGS AND PATTERNING

(71) Applicant: Inpria Corporation, Corvallis, OR (US)

(72) Inventors: Brian J. Cardineau, Corvallis, OR (US); Robert E. Jilek, Philomath, OR (US); Kai Jiang, Corvallis, OR (US); Alexander C. Marwitz, Corvallis, OR (US)

(21) Appl. No.: 18/830,797

(22) Filed: Sep. 11, 2024

Related U.S. Application Data
(60) Provisional application No. 63/537,977, filed on Sep. 12, 2023.

(51) Int. Cl. G03F 7/004; G03F 7/16; G03F 7/20

(52) U.S. Cl. CPC G03F 7/0042; G03F 7/0048; G03F 7/162; G03F 7/2004

(57) ABSTRACT

Organotin patterning compositions can incorporate Sn—F bonds to improve pattering performance. A precursor solution for a radiation patterning composition can comprise a blend of an organic solvent, an organotin composition represented by the formula RSnL₃, and a compound capable of generating Sn—F bonds wherein R is a substituted or unsubstituted hydrocarbyl ligand with 1 to 31 carbon atoms and an Sn—C bond and L is a hydrolysable ligand. The fluoride source can be an ammonium fluoride. The patterning structure on a substrate surface has RSnFₙ moieties, generally within an oxo-hydroxo network.

### CROSS REFERENCE TO RELATED APPLICATIONS

This application claims priority to copending U.S. provisional patent application 63/537,977 filed Sep. 12, 2023 to Cardineau et al., entitled “Organotin Photoresist Compositions Having Fluoride Generator Compounds,” incorporated herein by reference.

### FIELD OF THE INVENTION

The invention relates to organotin radiation patterning compositions with fluoride sources that can introduce tin fluoride bonds. The invention further relates to organotin patterning compositions that are effective for high resolution EUV patterning and that have lower dose requirement to achieve desirable patterning results.

### BACKGROUND OF THE INVENTION

Extreme ultraviolet lithography (EUV) is currently being used in high-volume semiconductor manufacturing, and metal organic resists (MOR) have been shown to be high-performance photoresists for use in EUV lithography. EUV lithography generally involves complex processing and expensive machinery, and it is generally desirable to improve MOR photoresist performance, such as by reducing patterning dose requirements, in order to maximize wafer throughput and, thus, to reduce the cost of EUV lithography.

### SUMMARY OF THE INVENTION

One aspect of the invention pertains to organotin photoresist solution compositions having a compound capable of generating Sn—F bonds upon exposure to radiation.

Another aspect of the invention pertains to organotin photoresist solution compositions comprising an ammonium fluoride compound represented by the formula NR′₄F, where R′ is hydrogen or an alkyl group having from 1 to 6 carbons.

In a further aspect, the invention pertains to a precursor solution for a radiation patterning composition comprising a blend of an organic solvent, an organotin composition represented by the formula RSnL₃, and a compound capable of generating Sn—F bonds wherein R is a substituted or unsubstituted hydrocarbyl ligand with 1 to 31 carbon atoms and an Sn—C bond and L is a hydrolysable ligand.

In some aspects, the invention pertains to a precursor solution for a radiation patterning composition comprising a blend of an organic solvent, an organotin composition represented by the formula RSnL₃, and a compound capable of generating fluoride ions during exposure to EUV radiation or a post-exposure bake.

In additional aspects, the invention pertains to a photoresist precursor composition comprising a mixture of one or more organotin compounds represented by the formula RSnL₃, where R is a saturated or unsaturated linear, branched, cyclic, aromatic hydrocarbyl group with 1 to 31 carbon atoms optionally substituted with heteroatoms and L is a hydrolysable ligand, and an ionic fluoride compound represented by the formula NR^{a}R^{b}R^{c}R^{d}F, where R^{a}, R^{b}, R^{c}, and R^{d} are independently hydrogen or an alkyl group having from 1 to 6 carbon atoms or a mixture thereof.

In other aspects, the invention pertains to a method of forming a photoresist solution having Sn—F bonds, the method comprising mixing an organotin precursor represented by the formula RSnL₃ and a fluoride source compound represented by the formula NR^{a}R^{b}R^{c}R^{d}F, where R^{a}, R^{b}, R^{c}, and R^{d} are independently hydrogen or an alkyl group having from 1 to 6 carbon atoms or a mixture thereof in an organic solvent to form the photoresist solution having Sn—F bonds, wherein R is a substituted or unsubstitutedhydrocarbyl ligand with 1 to 31 carbon atoms and an Sn—C bond and L is a hydrolysable ligand.

In further aspects, the invention pertains to a structure comprising a substrate and a patterning material on a surface of the substrate wherein the patterning material comprises RSnFₙ moieties where 0<n≤1 and R is a substituted or unsubstituted hydrocarbyl ligand with 1 to 31 carbon atoms and an Sn—C bond.

Moreover, the invention pertains to a method of patterning an organotin material having Sn—F bonds, the method comprising the step of irradiating the organotin material with patterned EUV radiation at a dose corresponding to at least 8% lower than a corresponding dose for the equivalent non-fluorinated organotin patterning material to provide a patterned material with an equivalent critical dimension at the same coating thickness.

### BRIEF DESCRIPTION OF THE DRAWINGS

FIG. 1 is a ¹⁹F NMR spectrum of a concentrated solution prepared by combining tert-butyltin tris(pentan-3-lyoxide), ammonium fluoride, and 1-propanol.

FIG. 2 is a ¹¹⁹Sn NMR spectrum of the concentrated solution of FIG. 1.

FIG. 3 is a ¹⁹F NMR spectrum of a concentrated solution prepared by combining iso-propyltin tris(sec-butoxide), ammonium fluoride, and 4-methyl-2-pentanol.

FIG. 4 shows a set of ESI-MS spectra for photoresist solutions P1-P4, prepared by mixing tert-butyltin tris(pentan-3-lyoxide) and ammonium fluoride, at different molar ratios, with a solvent having a controlled amount of water.

FIG. 5 is a set of contrast curves for coated wafers that were prepared from either precursor solutions incorporating ammonium fluoride and or a control precursor solution.

FIG. 6 is an array of 15 CD-SEM images of a silicon substrate with an organotin resist patterned via EUV lithography to form 28-nm pitch lines with each image from the field with an average line CD closest to 14 nm with the top row of five SEM images corresponding to a post-exposure bake (PEB) temperature of 170° C., with the second row of five SEM images corresponding to processing with a PEB temperature of 180° C., with the bottom row of five SEM images corresponding to processing with a PEB temperature of 190° C., in which the five images in each row correspond to a resist film prepared with a precursor solution having NH₄F additive (A), tetramethyl ammonium fluoride additive (B), tetrabutyl ammonium fluoride additive (C), or no fluoride additive (Control 1 and Control 2).

FIG. 7 is a bar chart of the EUV dose for each of the images in FIG. 6.

### DETAILED DESCRIPTION

The radiation sensitivity of organotin photoresists can be improved by the presence of fluoride generators within a precursor solution that then is incorporated into a resulting organometallic matrix following solvent removal. The fluoride generators can produce fluoride anions (F⁻) that can function as ligands for tin within an organometallic composition. In some embodiments, some F⁻ species can become bound to tin species in the precursor solutions. In some embodiments, during exposure of the organometallic matrix to radiation and/or heating, the fluoride generators can produce reactive fluoride within the matrix that can result in the formation of tin-fluoride bonds. In further embodiments, F⁻ ligands may become associated with tin atoms at various times during processing, and the precise mechanisms and degree of ligand formation may depend on the specific species and processes. The organometallic patterning compositions generally have RSn moieties, where R is an organo ligand that can be radiation sensitive. The patterning compositions formed on a substrate surface form an oxo-hydroxo network that is restricted from fully condensing to a metal oxide through the presence of the organo-ligands. Radiation driven cleavage of the organo-ligand results in a high contrast irradiated material with a virtual image. It has been found that the presence of fluoride ligands introduced through the use of fluoride generating species, such as an ammonium fluoride, is found to reduce the radiation does needed for patterning without significantly compromising contrast. Without wanting to be limited by theory, the presence of tin-fluoride bonds within the organotin matrix may reduce the activation energy of the tin-carbon bonds within the matrix, and can thus improve the radiation sensitivity of the material.

Improving photoresist performance is desired in order to reduce the cost of manufacturing and to improve the yield of semiconductor device manufacturing. Organometallic materials, particularly those based on organotin compositions, have been shown to be high-performance photoresists that enable patterning of high-resolution and high-fidelity patterns. Organotin photoresists have been broadly described in U.S. Pat. No. 9,310,684 to Meyers et al., entitled “Organometallic Solution Based High Resolution Patterning Compositions,” in U.S. Pat. No. 10,642,15 to Meyers et al., entitled “Organometallic Solution Based High Resolution Patterning Compositions and Corresponding Methods,” and in U.S. Pat. No. 10,228,618 to Meyers et al., entitled “Organotin Oxide Hydroxide Patterning Compositions, Precursors, and Patterning”, all of which are incorporated herein by reference. To the extent that radiation dose can be reduced without compromising patterning performance, process times can be reduced since dose effectively correlates with irradiation time, so a reduction in dose increases throughput and increases efficiencies of capital equipment use.

In general, these organotin photoresist materials are deposited as coatings formed from precursors in which Sn atoms in the coating are associated in an oxo-hydroxo network through Sn—OH and Sn—O—Sn bonds along with intact Sn—C bonds associated with the organo ligands. The intact Sn—C bonds prevent extended dense network formation, and thus the as-deposited materials generally are soluble in suitable organic solvents and developers. Exposure of organotin coatings to appropriate radiation sources, such as extreme ultraviolet (EUV), ultraviolet (UV), electron beams, and the like, results in cleavage of the Sn—C bond and allows for further densification of the exposed area, decreasing solubility, thereby increasing the solubility contrast between exposed and unexposed regions. In this way, a physical pattern can be realized after development.

High contrast with respect to radiation exposure provides for high resolution lines and low line width roughness. While not wanting to be limited by theory, the presence of fluoride generators in the organotin composition may reduce the activation energy needed to cleave Sn—C bonds, and the radiation sensitivity of the organotin material can be improved as a result. The presence of Sn—C bonds within the as-deposited organotin material generally results in a hydrophobic organotin film, and exposure to radiation generally results in a more hydrophilic material. The presence of fluoride ligands provides notable improvement to the processing to form the latent image. The precise mechanism or mechanisms remain unclear, and it seems likely that multiple effects are influencing the results. Results suggest that the presence of fluoride ligands roughly maintain or improve thermal stability while improving radiation sensitivity. Improvement in radiation sensitivity can result from one or more mechanisms, which can be explored in future studies. In any case, the result is an ability to reduce effective dose for patterning, while maintaining high contrast leading to good resolution and pattern properties.

The mechanism and timing of formation of Sn—F ligands is not completely clear and likely depends on the specific species and conditions involved. Specifically, the specific fluoride generator, the specified organotin, the solvent and process conditions may all influence the structures in solution. In addition, upon depositing the precursor solution and removal of solvent, the resulting structures of the material may still be influenced by the species and process conditions. In some embodiments, Sn—F bonds may form in solution. In some embodiments, which may not be mutually exclusive, exposure of the organotin material containing fluoride generators to radiation and/or heating can lead to cleavage of tin-carbon bonds and the formation of Sn—F bonds, as well as Sn—O—Sn and/or Sn—OH bonds which can yield a higher polarity and more hydrophilic material, and drives improved chemical contrast between the radiated and the non-irradiated material. Following cleavage of the C—Sn bond due to radiolysis, radiation induced thermolysis, or thermolysis, there is also the possibility of forming C—F bonds, which may stabilize the cleaved organic moiety and/or facilitate its removal from the material. Regardless of the mechanism and timing for the imposition of the F⁻ on the bonding structure, the effects can be very desirable and impressive. The difference in hydrophilicity/polarity between irradiated and non-irradiated regions of the organotin film can enable both positive-tone processing, wherein the irradiated material is removed during development, and negative-tone processing, wherein the non-irradiated material is removed during development, and the desired tone can be generally be achieved through appropriate selection of developer, for example, with organic-based solvents for negative-tone processing and with aqueous-based solvents for positive-tone processing. Examples below are presented for negative tone patterning.

The presence of fluoride generators within the organotin material can lead to the formation of tin-fluoride bonds and enhance cleavage of tin-carbon bonds within the irradiated regions of the material, and thus reducing the dose needed to pattern the material. This effect is demonstrated in the Examples. Tin-fluoride bonds are also desirable due to their high hydrolytic and thermal stability, which can reduce their susceptibility to post-exposure effects, such as reactions with ambient humidity, delayed processing, and decomposition in post-exposure bake (PEB) processes. Furthermore, fluoride is known to have a higher EUV absorbance than C, H, and O and can thus enhance the absorbance of EUV radiation by the photoresist film.

The presence of tin-fluoride bonds can also improve the radiolysis-induced thermolysis behavior of the organotin photoresist compositions. Generally, after irradiation, the Sn—C bonds within the irradiated regions of the material are cleaved. It has been discovered that the thermal stability of the hydrocarbyl compounds remaining in the material after irradiation is significantly reduced, and their thermal stability decreases with decreasing Sn—C concentration. In other words, as the concentration of Sn—C bonds in the irradiated material is reduced, the thermal stability of the remaining Sn—C bonds in the irradiated material is also reduced. As Sn—F bonds are formed from the fluoride generator compositions described herein, the stability of the Sn—C bonds is further reduced which can enhance chemical contrast between the irradiated and non-irradiated regions of the film. After exposure to radiation where an initial amount of Sn—C bonds are cleaved and Sn—F bonds are present and/or formed, a subsequent bake can drive further cleavage of Sn—C bonds via thermolysis in a phenomenon referred to as a radiolysis induced thermolysis process

The fluoride generators are generally stable compounds that can be incorporated into the organotin photoresist matrix during deposition of the precursor solution to form the photoresist film. The fluoride source can then provide a fluoride anion to react in solution and/or with the organotin matrix to form tin-fluoride bonds. Generally, the fluoride generators can be thermally stable compounds that can generate fluoride anions due to solvent interactions that can favor the nucleophilic nature of the fluoride anions.

In some embodiments, the fluoride generators can comprise ionic compounds such as ammonium fluoride, alkylammonium fluoride, and quaternary ammonium fluoride compounds represented by the formula NR^{a}R^{b}R^{c}R^{d}F, where R^{a}, R^{b}, R^{c}, and R^{d} are independently hydrogen or an alkyl group having from 1 to 6 carbon atoms, and all of which are generally referred to herein as ammonium fluorides. A subgenus of these ammonium fluoride compounds are NR′₄F where R′ is hydrogen or an alkyl group having from 1 to 6 carbons, e.g., R=methyl, ethyl, propyl, butyl, pentyl, hexyl, and their respective isomers, such as iso-propyl, tert-butyl, and the like. Examples are directed to inorganic ammonium fluoride, NH₄F, tetramethyl ammonium fluoride, and tetrabutyl ammonium fluoride. The fluoride generators compounds provide fluoride anions not bound to a metal, which have been referred to in the art as “naked fluoride.” The fluoride anions can then be available for bonding to tin. In alcohol solvents, the ammonium fluoride may be effective to provide the fluoride anion for nucleophilic substitutions. These ammonium fluoride compounds have been used for introducing fluoride substituents in organic compounds through nucleophilic substitutions. In solution, the fluoride anions may be in equilibrium in various bonding configurations depending on the particular solvent, concentrations, particular other parameters and other parameters.

The results in the Examples suggest that at least some bonding of F⁻ to the tin in solution when the cation of the reactant is NH₄⁺. It is not known presently if the fluoride bonds to tin at a free hexagonal bonding site, displaces an alkoxide group: RSnFOOH⁻ or RSnOF+⁻OR′, potentially some proportion of each, or a combination of both. Bonding at a free bonding site can result in the formation of a fluorinated salt complex, such as represented by the formula NH₄⁺[RSnL₃F]⁻. Results in the examples suggest some of each type of bonding may be taking place. The details of the reaction and mechanism are presently not particularly significant other than the fact that Sn—F bonds can form. In principle, fluoride ligands can bridge between tin atoms. SnF₄ has an unusual crystal structure with octahedrally coordinated tin having four bridging planar fluorine atoms and two opposing apex non-bridging fluorine atoms. Thus, the fluoride ligand, in principle, can provide various bonding options with respect to the tin material, which potentially may all be available in the patterning material.

The generation of tin fluoride bonds can lead to the formation of a fluorinated organotin oxide hydroxide network. While not wanting to be limited by theory, it is believed that the fluorine atoms generally prefer to form terminal Sn—F bonds rather than bridges between tin atoms which can reduce the formation of defects such as microbridges. The substitution of non-bridging Sn—F bonds for bridging Sn—OH—Sn bonds can improve the solubility of the unexposed and lightly exposed material by hindering the formation of extended oxide hydroxide networks, and therefore can aid in the reduction of defects such as microbridges and scum. Owing to their tendency to form terminal Sn—F bonds, the addition of fluoride can reduce the average domain size in the photoresist coating. After exposure to radiation and development of the pattern, finer features can be formed with low roughness because of the smaller domain sizes afforded by the presence of the tin-fluoride bonds which allow for finer controlled removal of material.

In the coating, the solvent has been removed, and the fluoride ions from the fluoride source may or may not be bound to tin. To the extent that they are not already bound to tin and while not wanting to be limited by theory, radiation exposure and/or heating of the organotin composition having fluoride generators, for example, ammonium fluorides, can generally lead to decomposition of the ammonium fluoride compound and promote the formation of Sn—F bonds according to the following reactions:

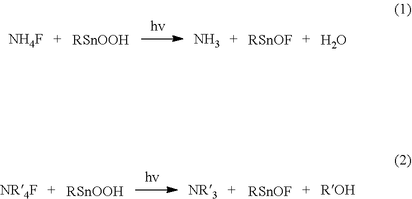

In reactions 1 and 2, R and R′ are defined as above. Some ammonium fluoride compounds are indicated to decompose at temperatures used during processing of the organotin coatings. It is not known if they would still thermally decompose dispersed through the coating material, but the decomposition may favor formation of tin-fluoride bonds as noted above. Again, at this time, the precise mechanism and timing of forming fluoride-tin bonds is not significant as long as a desired degree of formation of fluoride-tin bonds is achieved during patterning.

Various approaches can be used to form the precursor solutions, and the resulting compositions may or may not be independent of the process order. In some embodiments, the fluoride generators can be added to the photoresist solution by dissolving an appropriate mass of the compound into the photoresist solution composition. These solutions can be formed at an initial concentration, and subsequently diluted to achieve a desired concentration for deposition. Fluoride generators and solvents can be selected appropriately to achieve desired solubility for a tin precursor concentration. In some embodiments, the fluoride generator compound can be first dissolved into an appropriate solvent to form a fluoride generator solution that can then be added to the photoresist solution composition. Again, these solutions can be formed at an initial concentration and subsequently diluted. Achievement of dissolved ammonium fluoride can be allowed to take place over an extended period of time, and the initial mixtures can be appropriately stirred for a sufficient period of time, such as minutes, hours, overnight or longer, to complete the dissolving process.

The concentration of the fluoride generator can be represented as moles fluoride relative to the Sn. Based on a selected concentration of tin in the precursor solution, the concentration of fluoride generator follows from the tin concentration and the molar ratio. In some embodiments, the fluoride generator compounds can be in the solution at a mole ratio to tin of 0.001 to about 1, in further embodiments from about 0.0015 to about 0.75, in some embodiments from about 0.002 to about 0.6, in additional embodiments from about 0.002 to about 0.5, in further embodiments from about 0.0035 to about 0.45, in additional embodiments from about 0.005 to about 0.4 and in some embodiments from about 0.0075 to about 0.3 moles fluoride per mole of tin. These mole ratios can similarly be expressed as the ratio of tin to fluoride generator, such as ammonium fluoride, for example, about 20:1 to about 1.5:1, which is equivalent to about 0.05 to about 0.667 as a mole ratio of fluoride generator to tin. A person of ordinary skill in the art will understand that additional ranges of mole ratios of fluoride ions per tin are contemplated and are within the present disclosure.

As used herein, and as generally consistent with usage in this field, “organotin,” “hydrocarbyl tin”, and “alkyl tin” terms can be used interchangeably, and likewise “monoalkyl” can be used interchangeably with “monoorgano” or “monohydrocarbyl”. The “alkyl” (i.e., “organo”) ligands suggest bonding to the tin via Sn—C bonds wherein the carbon is generally sp³ or sp² hybridized and forms a bond that is generally not hydrolysable through contact with water. The “alkyl” group can optionally have internal unsaturated bonds and hetero-atoms, i.e., distinct from carbon and hydrogen, that are not involved in bonding with the tin. A chemical group bonded to a metal atom is generally referred to as a ligand in the art. A reference to a “hydrolysable ligand” generally refers to a ligand bound to the Sn with a hydrolysable bond, such as an alkoxide ligand which is bound at an oxygen atom with an organo substituent on the oxygen (e.g., —OR′) or an amide ligand which is bound at a nitrogen atom with an organo substituent(s) on the nitrogen (e.g., —NR¹R²). Synthesis methods have been developed to yield monoalkyl tin trialkoxides in high yield and with low (non-tin) metal and polyalkyltin (i.e., polyhydrocarbyl, e.g., dialkyltin, trialkyltin) contaminants following straightforward purification.

Organotin photoresist precursor compositions generally comprise one or more hydrolytically sensitive organotin species represented by the overall formula RₙSnL₄₋ₙ, where n=0.5-3 (or in further embodiments n=0.75-2.0, where n is an average for the species present), and L is a ligand that forms a hydrolysable bond with the Sn, such as a dialkylamide (—NR′₂), an alkoxide (—OR′), an acetylide (—CCR′), a carboxylate (—COOR′), and/or the like. In general, photoresist compositions comprising monoalkyl tin compositions (n=1) have been of primary interest and correspond to present commercial organotin photoresists. Generally, R is an organo group with 1 to 31 carbon atoms with the organo group forming a C—Sn bond, and R′ is an organo group with 1 to 10 carbon atoms. In some embodiments, R can comprise ≤10 carbon atoms and can be, for example, methyl, ethyl, n-propyl, isopropyl, n-butyl, t-butyl, isobutyl, t-amyl, propenyl, butenyl, pentenyl, or isomers thereof. The R group can be a linear, branched, (i.e., secondary or tertiary at the metal-bonded carbon atom), or cyclic hydrocarbyl group. Each R group individually and generally has from 1 to 31 carbon atoms with 3 to 31 carbon atoms for the group with a secondary-bonded carbon atom and 4 to 31 carbon atoms for the group with a tertiary-bonded carbon atom, optionally with unsaturated or aromatic carbon bonds. Groups with unsaturated carbon bonds and no hetero atoms can be described as a branched or linear group with an overall stoichiometry of CₙH₂₍ₙ₋₁₎₊₃, n=1 to 31. In particular, branched alkyl (unsaturated) ligands can be desirable for some patterning compositions. The formation of the oxo-hydroxo coating material can comprise deposition of one or more tin composition(s) with hydrolysable bonds, such as RSnL₃, where L is a hydrolysable ligand, such as an alkoxide, a dialkyl amine, an acetylide, or other suitable hydrolysable ligand. The hydrolysable ligands can be hydrolyzed to form the oxo-hydroxo network during deposition of the coating and/or in the coating following deposition, i.e., completing the hydrolysis after deposition. Applicant has developed methodologies to efficiently and effectively form a wide range of patterning compositions with different R groups, optionally with various hetero atoms, with C—Sn bonds, as described further in published U.S. patent application 2022/00064192 to Edson et al., entitled “Methods to Produce Organotin Compositions With Convenient Ligand Providing Reactants,” incorporated herein by reference.

In general, the precise structure of species, which may be transient, in solution is not known, but gelling is controlled to help maintain processability of the precursor solution and avoid instability. It has been found that controlling the amount of water in the precursor solution can be desirable for process uniformity without excessively sacrificing shelf life, as described further below. In some cases, organotin photoresists can comprise cluster compositions where multiple RSn moieties are linked through Sn—O—Sn, Sn—OH—Sn, or Sn—COO—Sn bonds such as, for example, in the dodecameric “football” clusters [(RSn)₁₂O₁₄(OH)₆]²⁺ and the hexameric “drum” clusters [RSnOOCR′]₆. These organotin compositions are generally dissolved in appropriate solvents to form organotin photoresist solutions. The use of tin dodecamer clusters for patterning is described in U.S. Pat. No. 11,392,028 to Cardineau et al., entitled “Tin Dodecamers and Radiation Patternable Coatings With Strong EUV Absorption,” incorporated herein by reference. The fluoride generator compounds described herein can generally be dissolved in these organotin photoresist solutions. In some embodiments, the fluoride generator compounds can be added to and/or dissolved in the organotin photoresist composition. In other embodiments, the fluoride generator compounds can be added to and dissolved into a solvent to form a fluoride generator compounds solution that can then be formulated into the organotin photoresist solution. The solvent used to dissolve the fluoride generator can be selected to be the same as the precursor solution solvent or soluble or miscible in the precursor solution solvent.

While a range of organotin compositions can be effective radiation patterning materials, organotin compounds with a single carbon-tin bond have been found to provide desirable processing for patterning in a commercial context, and the following discussion focuses on these mono-organo tin compositions. Thus, the organotin precursor compositions can comprise a group of compositions (RSnL₃) that can be hydrolyzed with water or other suitable reagent under appropriate conditions to form the monohydrocarbyl tin oxo-hydroxo patterning compositions, which, when fully hydrolyzed, can be represented by the formula RSnO_{(1.5-(x/2))}(OH)ₓ where 0<x≤3. In general, R is a hydrocarbyl ligand substituted or unsubstituted with heteroatoms, and L is a hydrolysable ligand, as further described below. It can be convenient to perform the hydrolysis to form the oxo-hydroxo compositions in situ, such as during deposition and/or following initial coating formation. In particular, triamides (L=amide) and trialkoxides (L=alkoxide) can be desirable ligands for use in hydrolyzing conditions for forming radiation sensitive coatings for patterning. While the terminology follows convention for the hydrolysable ligands, it should be noted that these can comprise organo substituents of various substitutions with potential unsaturated bonds or heteroatom substitutions. The various precursor compounds with hydrolysable ligands generally carry forward the R-ligand to tin through pre-irradiation processing and are synthesized with this perspective. Hydrolysable ligands include, for example, alkoxide (hydrocarbyl oxide), acetylide or amide moieties. Suitable alkoxide ligands include, for example, tert-butoxide, sec-butoxide, pentan-3-lyoxide (i.e., alkoxide of pentan-3-ol), or tert-amyloxide. The organotin precursor compositions can generally be synthesized as described, for example, in U.S. Pat. No. 10,787,466 to Edson et al., entitled “Monoalkyl Tin Compounds with Low Polyalkyl Contamination, Their Compositions and Methods”, and in published U.S. patent application 2022/0064192 to Edson et al., entitled “Methods to Produce Organotin Compositions with Convenient Ligand Providing Reactants,” both incorporated herein by reference.

The fluoride generator compounds are combined with precursors in a solvent to form precursor solutions for the organotin patterning compositions for delivery to a substrate. Solvents for the organotin precursors are generally suitable for dissolving the fluoride generator compounds or can be selected accordingly.

The precursor solution generally comprises organometallic precursor compositions, fluoride generator compounds, and an organic solvent. The resist precursor composition can be conveniently specified based on tin ion molar concentration. In general, the resist precursor solution generally comprises from about 0.0025 M to about 1 M tin cation, in some embodiments from about 0.004M to about 0.9M, in further embodiments from about 0.005 M to about 0.75 M, also in some embodiments from about 0.01M to about 1M, and in additional embodiments from about 0.01 M to about 0.5 M tin cation. With respect to the fluoride generator compounds, these can be specified as a mole ratio relative to the tin or as a molarity. The fluoride generator compounds can be in the solution at a mole ratio to tin of 0.001 to about 1, in further embodiments from about 0.0015 to about 0.75, in some embodiments from about 0.002 to about 0.6, in additional embodiments from about 0.002 to 0.5, in further embodiment from about 0.0035 to about 0.45, in additional embodiments from about 0.005 to about 0.4 and in some embodiments from about 0.0075 to about 0.3 moles fluoride per mole of tin. Similarly, the precursor solution can comprise fluoride generator compounds at a concentration from about 0.000025M to about 0.75M, in some embodiments from about 0.00005M to about 0.4M in further embodiments form about 0.000075M to about 0.35M and in additional embodiments from about 0.0001M to about 0.2M. In some embodiments, multiple fluoride generator compounds can be present wherein the sum concentration of all the fluoride generator compounds is within the ranges described above. A person of ordinary skill in the art will recognize that additional concentration ranges and values within the explicit ranges above are contemplated and are within the present disclosure.

Suitable organic solvents include, for example, alcohols or blends thereof. Generally, the solvents are at least 50 weight percent alcohols with any remaining organic solvent liquids being soluble in the alcohol, such as an alkane (such as pentane or hexane), an aromatic hydrocarbon (such as toluene), ether (such as diethyl ether, C₂H₅OC₂H₅), or mixtures thereof. In some embodiments, the solvent is at least 90 weight percent alcohol, and the solvent can be effectively alcohol with just trace impurities of other compounds. Suitable alcohols are generally monomeric alcohols with a melting point of no more than about 10° C., such as methanol, ethanol, propanol, butanol, pentanol, hexanol, heptanol, octanol, nonanol, decanol, branched versions thereof, and mixtures thereof. It has been found that controlling the water level can result in consistent and stable precursor solutions. In particular, the water level can be adjusted, generally by addition of small amounts of water to the solvent. to achieve the target water levels, generally no more than about 10,000 ppm by weight, in additional embodiments from about 300 ppm by weight to about 2500 ppm by weight, in further embodiments from about 200 ppm by weight, and in additional embodiments from about 250 ppm to about 1000 ppm by weight water. A person of ordinary skill in the art will recognize that additional ranges within the explicit ranges above are contemplated and are within the present disclosure. The use of water content adjustment is discussed further in U.S. Pat. No. 11,300,876 (herein the '876 patent) to Jiang et al., entitled “Stable Solutions of Monoalkyl Tin Alkoxides and Their Hydrolysis and Condensation Products,” incorporated herein by reference.

As noted above, the photoresist precursor solutions with organotin compositions and fluoride generators can be used to form radiation-patternable organotin oxo hydroxo materials incorporating the fluoride generators and/or pre-formed Sn—F moieties from solution, and such coatings can be formed using any suitable deposition method known in the art. Spin coating can be particularly desirable for forming coatings using the fluoride generator containing photoresist precursor solutions. In a typical spin coating process, a volume of a photoresist solution is introduced onto the surface of a substrate, and the substrate is rotated at high speeds to drive rapid evaporation and hydrolysis processes, generally with atmospheric water, to enable the formation of a radiation patternable coating. In some embodiments, the substrate can be spun at rates (i.e., spin speeds) from about 500 rpm to about 10,000 rpm, in further embodiments from about 1000 rpm to about 7500 rpm, and in additional embodiments from about 2000 rpm to about 6000 rpm. The spin speed can be adjusted to obtain a desired coating thickness for a given precursor solution and for a given substrate size. The spin coating can be performed from about 5 seconds to about 5 minutes and in further embodiments from about 15 seconds to about 2 minutes. An initial low speed spin, e.g., at 50 rpm to 250 rpm, can be used to perform an initial bulk spreading of the composition across the substrate. A back side rinse, edge bead removal step, or the like can be performed with water or other suitable solvent to remove any edge bead. See, for example, U.S. Pat. No. 10,627,719 to Waller et al., entitled “Methods of Reducing Metal Residue in Edge Bead Region From Metal-Containing Resists,” incorporated herein by reference. A person or ordinary skill in the art will recognize that additional ranges of spin coating parameters within the explicit ranges above are contemplated and are within the present disclosure.

A substrate generally presents a surface onto which the coating material can be deposited, and the substrate may comprise a plurality of layers in which the surface relates to an upper most layer. The substrate surface can be treated to prepare the surface for adhesion of the coating material. Prior to preparation of the surface, the surface can be cleaned and/or smoothed as appropriate. Suitable substrate surfaces can comprise any reasonable material. Some substrates of interest include, for example, silicon wafers, silica substrates, other inorganic materials, polymer substrates, such as organic polymers, composites thereof and combinations thereof across a surface and/or in layers of the substrate. In some embodiments, the substrate can comprise a patterned structure such as described by Stowers et al. in U.S. Pat. No. 10,649,328, entitled “Pre-Patterned Lithography Templates, Process Based on Radiation Patterning Using The Templates And Processes To Form The Templates”, incorporated herein by reference.

The thickness of the coating generally can be a function of the precursor solution concentration, viscosity and the spin speed for spin coating. For other coating processes, the thickness can generally also be adjusted through the selection of the coating parameters. In some embodiments, it can be desirable to use a thin coating to facilitate formation of small and highly resolved features in the subsequent patterning process. For example, the coating materials after drying can have an average thickness of more than about 250 nanometers (nm), in additional embodiments from about 1 nm to about 50 nm, in other embodiments from about 2 nm to about 40 nm and in further embodiments from about 3 nm to about 25 nm. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the film. In general, the coatings are relatively uniform to facilitate processing. In some embodiments, such as high uniformity coatings on reasonably sized substrates, the evaluation of coating uniformity or flatness may be evaluated with, for example, a 1 centimeter edge exclusion, i.e., the coating uniformity is not evaluated for portions of the coating within 1 centimeter of the edge, although other suitable edge exclusions can be selected.

While heating may not be needed for successful application of the deposition process, it can be desirable to heat the coated substrate prior to irradiation to densify the coating material, to speed the processing, to remove residual solvent, to increase the reproducibility of the process, and/or to facilitate vaporization of the hydrolysis by-products, such as alcohols and/or amines. In embodiments in which heating of the coated substrate is performed prior to irradiation, the coated substrate can be heated to temperatures from about 45° C. to about 250° C., and in further embodiments from about 55° C. to about 225° C. The heating can generally be performed for at least about 0.1 minute, in further embodiments for about 0.5 minutes to about 30 minutes, and in additional embodiments from about 0.75 minutes to about 10 minutes. A person of ordinary skill in the art will recognize that additional ranges of heating temperatures and times within the explicit ranges above are contemplated and are within the present disclosure.

Generally, photoresist coatings can be patterned using radiation. Suitable radiation sources include extreme ultraviolet (EUV), ultraviolet (UV), or electron beam (EB) radiation. For fabrication of semiconductor devices, EUV radiation can be desirable due to its higher resolution compared to UV radiation, and its higher throughput compared to electron beam (EB)-based processing. Radiation can generally be directed to the substrate material through a mask or a radiation beam can be controllably scanned across the substrate to form a latent image within the resist coating. For EUV “masking” the patterns are formed using mirrors to reflect and direct light from a plasma source.

Following International Standard ISO 21348 (2007) incorporated herein by reference, ultraviolet light extends between wavelengths of greater than or equal 100 nm and less than 400 nm. A krypton fluoride laser can be used as a source for 248 nm ultraviolet light. The ultraviolet range can be subdivided in several ways under accepted Standards, such as extreme ultraviolet (EUV) from greater than or equal 10 nm to less than 121 nm and far ultraviolet (FUV) from greater than or equal to 122 nm to less than 200 nm. A 193 nm line from an argon fluoride laser can be used as a radiation source in the FUV. EUV light has been used for lithography at 13.5 nm, and can be generated from a Xe or Sn plasma source excited using high energy lasers or discharge pulses. Commercial sources of EUV photons include scanners fabricated by ASML Holding N.V. Netherlands. Soft x-rays can be defined from greater than or equal 0.1 nm to less than 10 nm.

The amount of electromagnetic radiation can be characterized by a fluence or dose which is obtained by the integrated radiative flux over the exposure time. For embodiments in which EUV radiation is used, suitable radiation doses can be from about 1 mJ/cm² to about 150 mJ/cm², in further embodiments from about 2 mJ/cm² to about 100 mJ/cm² in further embodiments from about 3 mJ/cm² to about 50 mJ/cm² and in some embodiments from about 10 mJ/cm² to about 60 mJ/cm². A person of ordinary skill in the art will recognize that additional ranges of radiation fluences within the explicit ranges above are contemplated and are within the present disclosure.

The coating material for development is believed to comprise RSnFₙ, but it has not been determined what range of values “n” may take in the coating at various stages of processing to development. It is known how much fluoride is initially added, but quantification of the amount that ultimately bonds to the tin has not been elucidated. Irradiated regions have reduced organic components, which is further reduced by a post exposure bake as described in the following. The coating still comprises an oxo-hydroxo network, but this is altered in some way by the fluoride ligands without significantly sacrificing contrast between irradiated and non-irradiated regions based on the patterning results.

Following exposure to radiation and the formation of a latent image, a subsequent postexposure bake (PEB) is typically performed. In some embodiments, the PEB can be performed at temperatures from about 45° C. to about 250° C., in additional embodiments from about 50° C. to about 190° C. and in further embodiments from about 90° C. to about 185° C. The post exposure heating can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of PEB temperatures and times within the explicit ranges above are contemplated and are within the present disclosure. The PEB can be designed to further consolidate the exposed regions without decomposing the un-exposed regions into a metal oxide.

Applicant has found that the PEB can contribute significantly to radiation induced thermolysis. In other words, the irradiated structures can initially undergo radiolysis so that irradiation induces cleavage of the hydrocarbyl ligands and removal of the material of product species formed form the cleaved ligands. But a PEB is found to further result in loss of additional organic moieties from the irradiated material, which can be termed radiation induced thermolysis since neither processing separately results in the same degree of loss of organic species from the material. The loss of organics from the material can be measured using infrared spectroscopy tuned to organic frequencies. It has been found that the presence of Sn—F bonds within the organotin matrix can improve radiation sensitivity, which suggests an improvement in the efficacy of radiolysis induced thermolysis. Furthermore, it is found that increasing the PEB temperature also improves the radiolysis induced thermolysis. In particular, for one example in the presence of Sn—F bonds, increasing the PEB temperature up to 190° C. resulted in the lowering of the dose to achieve line/space patterns with a critical dimension on the order of 14 nanometers (nm) without a significant change in line-width-roughness.

Following performing a PEB, development of the image involves the contact of the patterned coating material including the latent image to a developer composition to remove either the un-irradiated coating material to form the negative image or the irradiated coating to form the positive image. Irradiated regions of organotin oxide hydroxide coatings are generally hydrophilic and are thus soluble in aqueous bases and insoluble in organic solvents; conversely, non-irradiated regions are generally hydrophobic and are thus soluble in organic solvents and insoluble in aqueous bases. For negative tone imaging, the developer can be an organic solvent, such as the solvents used to form the precursor solutions.

Specifically, for positive tone imaging, suitable developers generally can be aqueous bases. In some embodiments, aqueous bases can be used to obtain sharper images. To reduce contamination from the developer, it can be desirable to use a developer that does not have metal atoms. Thus, quaternary ammonium hydroxide compositions, such as tetraethylammonium hydroxide, tetrapropylammonium hydroxide, tetrabutylammonium hydroxide or combinations thereof, are desirable positive tone developers. In general, the quaternary ammonium hydroxides of particular interest can be represented with the formula R₄NOH, where R=a methyl group, an ethyl group, a propyl group, a butyl group, or combinations thereof. The coating materials described herein generally can be developed with the same developer commonly used presently for polymer resists, specifically tetramethyl ammonium hydroxide (TMAH). Commercial TMAH is available at 2.38 weight percent. Furthermore, mixed quaternary tetraalkyl-ammonium hydroxides can be used. In general, the developer can comprise from about 0.5 to about 30 weight percent, in further embodiments from about 1 to about 25 weight percent and in other embodiments from about 1.25 to about 20 weight percent tetra-alkylammonium hydroxide or similar quaternary ammonium hydroxides. A person of ordinary skill in the art will recognize that additional ranges of developer concentrations within the explicit ranges above are contemplated and are within the present disclosure. For a positive tone developer, it can be desirable to dissolve material densified from a relatively high radiation dose, assuming that the non-irradiated material is not significantly removed. This opens up the process window further.

For the negative tone imaging, the developer can be an organic solvent, such as the solvents used to form the precursor solutions. In general, developer selection can be influenced by solubility parameters with respect to the coating material, both irradiated and non-irradiated, as well as developer volatility, flammability, toxicity, viscosity and potential chemical interactions with other process material. In particular, suitable developers include, for example, aromatic compounds (e.g., benzene, xylenes, toluene), esters (e.g., propylene glycol monomethyl ester acetate (PGMEA), ethyl acetate, ethyl lactate, n-butyl acetate, butyrolactone), alcohols (e.g., 4-methyl-2-pentanol, 1-butanol, isopropanol, 1-propanol, methanol), ketones (e.g., methyl ethyl ketone, acetone, cyclohexanone, 2-heptanone, 2-octanone), ethers (e.g., tetrahydrofuran, dioxane, anisole) and the like. Improved developer compositions have been described in published U.S. Patent Application No.: 2020/0326627 to Jiang et al., entitled “Organometallic Photoresist Developer Compositions and Processing Methods,” incorporated herein by reference. Improved developer solutions generally comprise a reference organic solvent composition and an additive composition having a higher polarity and/or hydrogen-bonding character than the reference solvent composition. In one example, an improved developer composition can comprise PGMEA and acetic acid. The development can be performed for about 5 seconds to about 30 minutes, in further embodiments from about 8 seconds to about 15 minutes and in addition embodiments from about 10 seconds to about 10 minutes. A person of ordinary skill in the art will recognize that additional ranges within the explicit ranges above are contemplated and are within the present disclosure.

For negative tone development, developer selection can be effectively influenced by solubility parameters with respect to the coating material, both irradiated and non-irradiated, as well as developer volatility, flammability, toxicity, viscosity and potential chemical interactions with other process material. Some useful developer compositions for these organotin oxide photoresists have been described in published U.S. Patent Application No. 2020/0326627 to Jiang et al., entitled “Organometallic Photoresist Developer Compositions and Processing Methods”, incorporated herein by reference. In particular, developers can have differing amounts of more polar or less polar components, which can be specified more specifically with solubility parameters. In some embodiments, the solvent blend can comprise at least two solvents with at least 55 volume % of one or more solvents each independently having a sum of Hansen solubility parameter δH+δP of no more than about 16 (J/cm³)^{1/2}, and with from about 0.25 volume % to about 45 volume % of one or more solvents each independently having a sum of Hansen solubility parameter δH+δP of at least about 16 (J/cm³)^{1/2}.

It has also been discovered that solventless development, also referred to as dry development, can be employed with organotin materials. Dry development can include, for example, selective removal of the irradiated or non-irradiated regions of the photoresist by exposing the material to an appropriate plasma or appropriate flowing gas. Dry development of organotin resists has been described in PCT Publication No. 2020/132281A1 by Volosskiy et al., entitled “Dry Development of Resists”, and in published U.S. Patent Application No. 2023/0100995 to Cardineau et al., entitled “High Resolution Latent Image Processing and Thermal Development”, both of which are incorporated herein by reference. In such dry development processes, development can be achieved by exposing the irradiated substrate to a plasma or a thermal process while flowing a gas comprising a small molecule reactant that facilitates removal of irradiated or non-irradiated regions. Following development, a rinse step can be conducted if desired to further remove undesired material from the pattern, and such methods have been described in published U.S. Patent Application No. 2020/0124970 to Kocsis et al., entitled “Patterned Organometallic Photoresists and Methods of Patterning,” incorporated herein by reference.

A rinse with an inert liquid, such as deionized water, can be used to remove residual developer and other debris. After completion of the development step, the coating materials can be heat treated to further condense the material and to further dehydrate, densify, or remove residual developer or rinse from the material. This heat treatment can be particularly desirable for embodiments in which the oxide coating material is incorporated into the ultimate device, although it may be desirable to perform the heat treatment for some embodiments in which the coating material is used as a resist for pattern transfer and ultimately removed if the stabilization of the coating material is desirable to facilitate further patterning. In particular, the bake of the patterned coating material can be performed under conditions in which the patterned coating material exhibits desired levels of etch selectivity. To differentiate this heating step, this can be referred to as a hard bake. In some embodiments, the patterned coating material can be heated to a temperature from about 100° C. to about 600° C., in further embodiments from about 175° C. to about 500° C. and in additional embodiments from about 200° C. to about 400° C. The heating can be performed for at least about 1 minute, in other embodiment for about 2 minutes to about 1 hour, in further embodiments from about 2.5 minutes to about 25 minutes. The heating may be performed in air, vacuum, or an inert gas ambient, such as Ar or N₂. A person of ordinary skill in the art will recognize that additional ranges of temperatures and time for the heat treatment within the explicit ranges above are contemplated and are within the present disclosure. Likewise, non-thermal treatments, including blanket UV exposure, or exposure to an oxidizing plasma such as O₂ may also be employed for similar purposes.

The patterned structures can be evaluated using automated imaging equipment and scanning electron microscope imagers are generally used. For example, specific commercial CD-SEM instruments can measure critical line dimensions (line widths) and can also evaluate defects, such as microbridging. For evaluation of photoresist performance, CD-SEM instruments are generally used to analyze and measure the patterns generated across multiple fields on multiple wafers. The coated wafers can be exposed to radiation at different doses within each wafer, resulting in an array of differently dosed patterns across the wafer (e.g., fields), which can each then be analyzed by the CD-SEM. In this way, the dose-to-size values for a target pattern with a given resist formulation or set of processing conditions can be collected.

In general, the improved radiation sensitivity provides for the use of a lower dose to achieve the same pattern resolution for a given set of processing conditions. In some embodiments, the patterning can be performed by irradiating the organotin material with patterned EUV radiation at a dose corresponding to at least about 8% lower, and in further embodiments, at least about 10% lower, than a corresponding dose for the equivalent non-fluorinated organotin patterning material to provide the equivalent critical dimension at the same coating thickness, the same PAB and PEB conditions, and using the same selected developer. The dose decreases can translate into reduced irradiation times and a correspondingly increased throughput.

### EXAMPLES

### Example 1: Preparation and Analysis of Organotin Precursor Solutions with Fluoride Additives

This example describes the preparation of organotin precursor solutions by combining a non-fluorinated organotin precursor composition, an ammonium fluoride compound, and a solvent. NMR analysis was used to establish the presence of Sn—F species in the prepared precursor solutions.

An appropriate quantity of tert-butyltin tris(pentan-3-yloxide) and ammonium fluoride (NH₄F) were combined, and then, an appropriate volume of 1-propanol was added to prepare a concentrated solution having a concentration of 1 M Sn and an initial concentration of 0.2 M NH₄F. The mixture was stirred overnight to afford a clear, concentrated stock solution, FA1. A second concentrated stock solution, FA2, was prepared in a similar manner by combining iso-propyltin tris(sec-butoxide), ammonium fluoride, and 4-methyl-2-pentanol to afford a clear, concentrated solution having a concentration of 1 M Sn and an initial concentration of 0.2 M NH₄F.

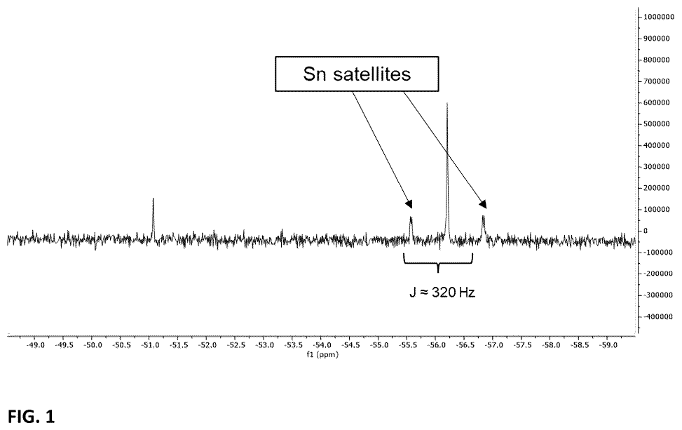

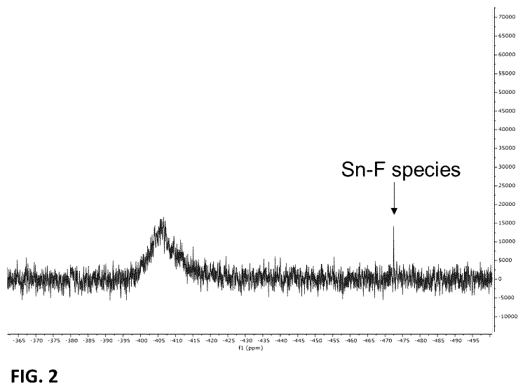

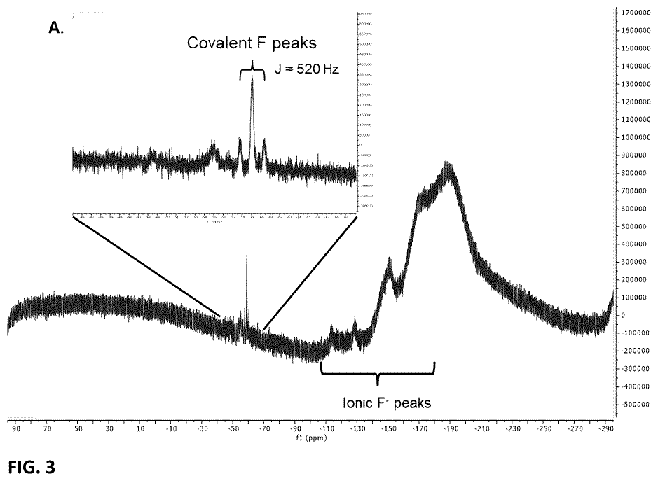

NMR analysis was conducted on solutions FA1 and FA2. Aliquots of each solution were taken without further dilution and ¹⁹F and ¹¹⁹Sn NMR analyses were conducted using a 500 MHz Bruker NMR spectrometer. FIG. 1 shows a ¹⁹F NMR spectrum for solution FA1. Two covalent fluoride peaks are observed at around −51 ppm and −56.3 ppm with the latter having two Sn satellite peaks (indicated by the arrows), ¹J(¹¹⁹Sn-¹⁹F)≈320 Hz, indicative of the presence of Sn—F bonds. FIG. 2 shows a ¹¹⁹Sn NMR spectrum of solution FA1. A broad peak at about −406 ppm is observed. This peak is correlated to Sn alkoxide species. A sharp peak at around −472.5 ppm is also observed. This sharp peak is correlated to the presence of a fluorinated Sn species. Similarly, FIG. 3 shows the ¹⁹F NMR spectrum of solution FA2, with inset A providing a zoomed view of the indicated region. The spectrum shows a peak at −59.1 ppm having Sn satellite peaks, ¹J(¹¹⁹Sn-¹⁹F)≈520 Hz, consistent with the presence of (covalent) Sn—F bonds. Additional peaks between about −110 ppm and −180 ppm are consistent with the presence of anionic F species.

The results suggest that a reaction between ammonium fluoride and organotin trialkoxides occurs to form a fluorinated organotin precursor solution having Sn—F bonds. In particular, the results suggest the formation of a complex salt with an ammonium ion and a tin/fluorine-containing ion, such as represented by the formula NH₄⁺[tBuSn(pentan-3-yloxide)₃F]⁻ (for solution FA1) or by the formula NH₄⁺[i-PrSn(sec-butoxide)₃F]⁻ (for solution FA2).

### Example 2: Analysis of Fluorinated Organotin Resist Precursor Solutions by ESI-MS

This example further demonstrates the presence of fluorinated organotin oxo-hydroxo species in organotin photoresist precursor solutions prepared with fluoride additives.

First, a set of concentrated stock solutions were prepared by mixing tert-butyltin tris(pentan-3-lyoxide) and ammonium fluoride in a 10:1 molar ratio, a 5:1 molar ratio, a 2:1 molar ratio, or a 1:1 molar ratio. Then each mixture was dissolved in a solvent blend of 32 wt. % 1-propanol/68 wt. % 1-pentanol containing 2000 ppm H₂O. The mixtures were stirred overnight to form stock solutions, S1, S2, S3, and S4, as summarized in Table 1.

TABLE 1

| Stock Solution | [Sn] M | [NH₄F] M | [Sn]:[F] |
|---|---|---|---|
| S1 | 0.65 | 0.065 | 10:1 |
| S2 | 0.65 | 0.130 | 5:1 |
| S3 | 0.65 | 0.325 | 2:1 |
| S4 | 0.65 | 0.650 | 1:1 |

Following formation of the stock solutions, photoresist solutions P1, P2, P3, and P4 were prepared from aliquots of S1, S2, S3, and S4, respectively, by diluting each stock solution 10-fold with the 32 wt. %/68 wt. % 1-propanol/1-pentanol solvent blend containing 2000 ppm H₂O to afford photoresist solutions having [Sn] concentrations of 0.065 M. Following dilution and prior to ESI-MS analysis, the photoresist solutions were filtered through a 0.62 um syringe filter.

The addition of 2000 ppm H₂O to the solvent blend was done to promote the production of organotin oxo clusters, such as the dodecameric Sn₁₂ species represented by the general formula [(tBuSn)₁₂O₁₄(OH)₆][OH]₂, from the t-butyl tin-based precursor composition. Previous work by Dakternieks et al. (J. Organomet. Chem. 476 (1994) 33-40) has shown that dodecameric n-BuSn₁₂ species are generally readily detectable via ESI-MS analysis as a doubly-ionized species, [(nBuSn)₁₂O₁₄(OH)₆]²⁺. In the present work, an anologous deprotonated singly-ionized dodecamer, corresponding to the formula [(tBuSn)₁₂O₁₅(OH)₅]⁺, is detected at an m/z value of 2434. Therefore, the presence of fluorinated dodecameric species was tested by comparing the m/z values for the dodecameric species observed in each sample with the reference value of 2434.

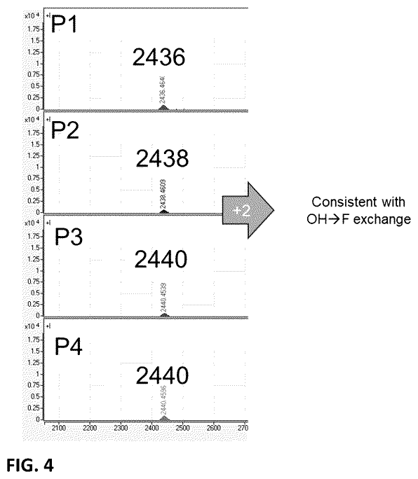

FIG. 4 shows the ESI-MS spectra for the photoresist solutions P1, P2, P3, and P4. Each photoresist solution showed a higher average m/z value as compared to the non-fluorinated dodecameric t-BuSn₁₂ species reference value of 2434. Furthermore, the average m/z value was observed to generally increase with an increase in the relative amount of F to Sn used to prepare the corresponding stock solution, with P1 having an average m/z of 2436 and P3 and P4 having an average m/z of 2440, as summarized in Table 4. In other words, it was observed that the m/z maxima of the peaks corresponding to the dodecamer species generally shifts to higher m/z values with increasing fluoride concentrations which suggests that the hydrolysis/condensation pathways that lead to the formation of organotin oxo/hydroxo species can proceed similarly in the presence of fluoride and can result in the substitution of Sn—OH bonds with Sn—F bonds. It was also observed that the dodecameric t-BuSn₁₂ peaks were shifted to n+2 higher m/z values for the increasing levels of ammonium fluoride between P1 and P2 and between P2 and P3. This result is consistent with increasing substitution of OH⁻ (m/z=17) for F⁻ (m/z=19). The formulae provided in Table 2 are consistent with the observed fluorinated dodecameric peaks.

TABLE 2

| Photoresist | Observed Average t- | |
|---|---|---|
| Solution | BuSn₁₂ m/z | Corresponding Sn₁₂ formula |
| P1 | 2436 | [(tBuSn)₁₂O₁₅(OH)₄F]⁺ |
| P2 | 2438 | [(tBuSn)₁₂O₁₅(OH)₃F₂]⁺ |
| P3 | 2440 | [(tBuSn)₁₂O₁₅(OH)₂F₃]⁺ |
| P4* | 2440 | [(tBuSn)₁₂O₁₅(OH)₂F₃]⁺ |

*this photoresist solution formed a precipitate during the course of the experiment

As noted in Table 4, photoresist solution P4 formed a precipitate during the course of the experiment, which seems to explain why the observed t-BuSn₁₂ m/z of 2440 did not follow the trend of increasing m/z. Additional experiments were performed with photoresist solutions prepared identically to P4 with the exception of using a solvent with a lower water content (300 ppm). It was observed that these lower-water content photoresist solutions did not form precipitates and also did not form dodecameric species that were detectable with ESI-MS analysis. The ESI-MS results for the low water solutions exhibited species having Sn and F atoms, which can reasonably be assumed to have Sn—F bonding, although the precise structures are not readily evaluated in contrast with the dodecamers. This result indicates that the precipitation of photoresist solution P4 was due to the higher water content causing the formation of insoluble hydrolysis/condensation products. Nevertheless, the incorporation of fluoride into soluble organotin oxo species formed in photoresist solution P4 was evident by the average m/z value of 2440.

Example 1 demonstrated the formation of fluorinated organotin precursor solutions having Sn—F bonds via mixing an organotin trialkoxide with an ammonium fluoride. The present example demonstrates that fluorinated organotin oxo-hydroxo clustrers are formed by contacting the alkoxide fluoride complex with water. The relatively high-water content of the photoresist solutions used in this example model the hydrolysis/condensation products that are formed during the deposition of photoresist solutions to form photoresist films. It is therefore expected that films produced from such fluorinated organotin precursor solutions comprise a fluorinated organotin oxo-hydroxo network with incorporated Sn—F bonds.

### Example 3: Fluorinated Organotin Films and Contrast Curves

This example shows the lowering of patterning doses for organotin photoresist films prepared with organotin precursor solutions to which ammonium fluoride has been added.

Organotin precursor solutions F1, F2, and C having the concentrations of Sn and F and the molar ratio of Sn:F as shown in Table 3 were prepared. First, concentrated stock solutions were prepared by mixing appropriate masses of ammonium fluoride and a 20 mol %/80 mol. % blend of organotin trialkoxides methyltin tris(tert-butoxide) and tert-butyltin tris(pentan-3-yloxide), respectively. Each mixture was dissolved in a solvent blend of 32 wt. % 1-propanol/68 wt. % 1-pentanol containing 350 ppm H₂O. The mixtures were stirred overnight to form concentrated fluorinated organotin precursor solutions having a total [Sn] concentration of 0.62 M. Following mixing, the concentrated stock solutions were diluted lox with the 32 wt. %/68 wt. % 1-propanol/1-pentanol solvent blend containing 350 ppm H₂O to afford photoresist solutions (F1 and F2) having [Sn] concentrations of 0.065 M. A control solution was also prepared by dissolving appropriate masses of the organotin precursor in the 32 wt. %/68 wt. % 1-propanol/1-pentanol solvent blend containing 350 ppm H₂O.

TABLE 3

| Precursor | | | |
|---|---|---|---|
| Solution | [Sn] M | [NH₄F] M | [Sn]:[F] |
| F2 | 0.065 | 0.013 | 5:1 |
| F1 | 0.065 | 0.0065 | 10:1 |
| Control | 0.065 | — | — |

The precursor solutions were spin-coated onto circular 300 mm Si wafers having a layer of approximately 10 nm spin-on-glass (SOG) to form photoresist coatings. The coated wafers were then subjected to a post-apply bake (PAB) of 130° C. for 60 s. Film thicknesses were measured via ellipsometry for each coated wafer to be about 28 nm.

Following the PAB, each coated wafer was then exposed on an ASML TwinScan NXE3400 EUV exposure tool to create a contrast array of exposed regions (i.e., pads) across each wafer wherein each exposed region received a different dose of radiation from about 1 mJ/cm² to 90 mJ/cm². Following EUV exposure, the films were then subjected to a post-exposure bake (PEB) of 180° C. for 60 s. Development was then conducted for each wafer with a 5 wt. % acetic acid in PGMEA solution. Finally, the wafers received a hard bake of 250° C. for 60 s. After completion of the hard bake, contrast curves were created for each wafer by measuring the thickness of each exposed region to create the plots of thickness vs. dose for each wafer. The thickness of the SOG layer (8.8 nm) was subtracted from the measured thickness of the resist. For clarity, the thicknesses were normalized to the maximum thickness observed for each curve (i.e., maximum thickness=1).

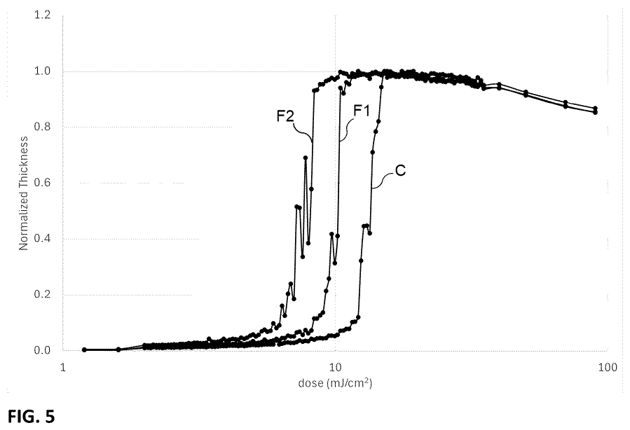

FIG. 5 shows the contrast curves for coated wafers that were prepared from F1, F2, and the Control (precursor solution C). The results, plotted on a log scale, show a significant reduction in patterning dose for increasing amounts of ammonium fluoride in the precursor solutions. The coated wafers prepared from precursor solutions F1 and F2 showed lower patterning doses than for the coated wafer prepared from the control precursor solution. The results indicate that the incorporation of the ammonium fluoride in the precursor solutions led to the presence of fluoride within the films, which led to the lowering of the dose required for patterning. The coated wafer prepared from precursor solution F1, having an [Sn]:[F] ratio of 10:1, resulted in a lower dose to gel than the coated wafer prepared from the fluoride-free control. The coated wafer prepared from precursor solution F2, having double the concentration of ammonium fluoride as precursor solution F1, resulted in an even lower dose to gel. Notably, the apparent contrast of the films, as indicated by the sharpness of the thickness transition, is similar. This indicates that the addition of fluoride to resist precursor solutions can improve the radiation sensitivity of a resist film while significantly maintaining high contrast between unexposed and exposed regions.

These results show that the addition of ammonium fluoride to an organotin photoresist precursor solution can improve the dose sensitivity of a photoresist film without a significant degradation of contrast.

### Example 4: EUV Patterning of Fluorinated Organotin Oxo-Hydroxo Films

This example demonstrates the improvements in EUV patterning of films produced from organotin photoresist precursor solution with an ammonium fluoride additive.

Photoresist precursor solutions were prepared by combining tert-butyltin tris(tert-butoxide), an ammonium fluoride compound, and a solvent according to Table 4.

The ammonium fluoride compounds used in this study were inorganic ammonium fluoride (“HNF”), tetramethyl ammonium fluoride (“MNF”), and tetrabutyl ammonium fluoride (“BNF”). The selected components for each precursor solution were combined and mixed according to Table 5.

TABLE 4

| | Solvent |
|---|---|
| Solvent | Code |
| 32% 1-propanol/68% 1-pentanol/300 ppm H₂O | Z1 |
| 55% 4-methyl-2-pentanol/45% 1-propanol/300 ppm H₂O | Z2 |

TABLE 5

| | | | | | F mol. % |
|---|---|---|---|---|---|
| Precursor | | Fluoride | Mix | Final [Sn] | relative to Sn |
| Solution | Solvent | compound | Method | M | ([Sn]:[F]) |
| S-A | Z1 | HNF | Conc. | 0.065 | 20% (5:1) |
| S-B | Z1 | BNF | Std. | 0.065 | 5% (20:1) |
| S-C | Z2 | MNF | Std. | 0.053 | 5% (20:1) |
| CS-1 | Z1 | none | Std. | 0.065 | n/a |
| CS-2 | Z2 | none | Std. | 0.053 | n/a |

Precursor solution S-A, containing HNF were mixed through the concentrated solution route followed by dilution with a solvent blend, described in Examples 1-3, and indicated as the mixing method “Conc.” in Table 5. Precursor solutions S—B and S—C were prepared by dissolving appropriate masses of BNF or MNF, respectively, into a mixture of tert-butyltin tris(tert-butoxide) and the solvent having the indicated final concentration of Sn. In this “standard” mixing method (“Std.”), no secondary dilution was performed. For each precursor solution, an amount of the fluoride compound was used to afford the indicated percent fluoride relative to Sn. Control precursor solutions (CS-1 and CS-2), having no fluoride compound added, were also prepared with solvents Z1 and Z2, respectively.

The precursor solutions were spin-coated onto circular 300 mm Si wafers having a layer of approximately 10 nm spin-on-glass (SOG) to form photoresist coatings. The coated wafers were then subjected to a PAB of 100° C. for 60 s. The resulting resist films are summarized in Table 6. Film thicknesses were measured via ellipsometry.

TABLE 6

| Resist Film | Precursor Solution | Thickness (nm) |
|---|---|---|
| A | S-A | 25.8 +/− 0.9 |
| B | S-B | 27.1 +/− 0.9 |
| C | S-C | 31.7 +/− 1.2 |
| Control 1 | CS-1 | 29.7 +/− 1.2 |
| Control 2 | CS-2 | 30.1 +/− 1.0 |

Following the PAB, each coated wafer was then exposed on an ASML NXE3400 TwinScan EUV exposure tool using a dose meander exposure scheme to from an array of line space patterns having a nominal dimensions of 14 nm on a 28 nm space (14p28) where each array member was printed at a different dose at different locations on the wafer. The exposed wafers were then subjected to a PEB of 170° C., 180° C., or 190° C. for 60 s followed by development with 5 wt. % acetic acid in PGMEA. Each wafer was then subjected to a hard bake of at 250° C. for 60 s.

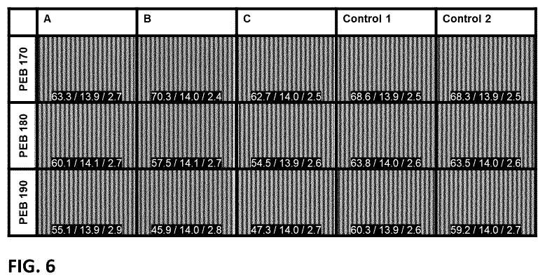

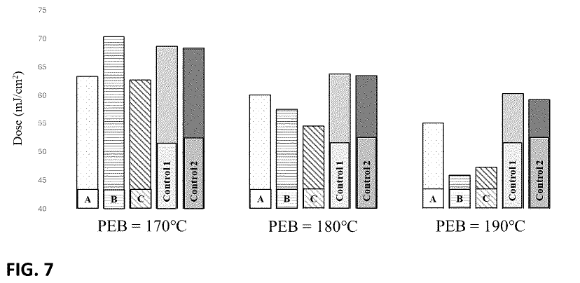

CD-SEM images were then collected using a commercial CD-SEM instrument and analyzed to determine the dose, critical dimension (CD, the average diameter of the holes) and line-width roughness (LWR) values for each image collected. CD-SEM images for each sample and PEB condition for 14p28 line-space patterns are shown in FIG. 6. Each image is labeled with the corresponding EUV dose (in mJ/cm²), CD (in nm), and LWR (in nm). FIG. 7 shows a bar graph of EUV dose vs PEB condition for each sample.

The samples prepared from the precursor solution containing HNF (A) showed lower doses at all PEB conditions, which is consistent with the contrast curves presented in Example 3 (FIG. 5). The samples prepared from precursor solutions with HNF or MNF as additives enabled lower patterning doses while maintaining the resolving capability of the photoresist to at least 14p28 with comparable LWR performance to the samples prepared without fluoride additives (Control 1 and Control 2). For the samples prepared from the precursor solution containing BNF (B), a higher patterning dose was observed for the lowest PEB condition compared to the control samples, though a lower LWR was also observed. As the temperature of the PEB increased from 170° C. to 180° C. to 190° C., a significant dose decrease, 70.3 mJ/cm² to 57.5 mJ/cm² to 45.9 mJ/cm², respectively, was observed at each temperature increase. The dose decrease seen as a function of PEB temperature for sample B was larger than for sample A or sample C. This result suggests that BNF has a significantly higher thermal effect than HNF or MNF. Similarly, MNF samples reduce the patterning dose more rapidly with PEB temperature than for HNF samples and the Controls.

These results demonstrate that the addition of an ammonium fluoride to an organotin photoresist precursor solution can improve patterning performance of a photoresist by lowering the patterning dose without an increase in LWR of the patterns. The results suggest that further improvements to patterning performance, such as lowing of the patterning dose and improving LWR simultaneously, may be possible via preparing precursor solutions with a blend of ammonium fluoride compounds.

### Further Inventive Concepts

A. A precursor solution for a radiation patterning composition comprising a blend of an organic solvent, an organotin composition represented by the formula RSnL₃, and a compound capable of generating fluoride ions during exposure to EUV radiation or a post-exposure bake.

A1. The precursor solution of inventive concept A further comprising a compound capable of generating Sn—F bonds.

A2. The precursor solution of inventive concept A1 wherein the compound capable of generating fluoride ions and the compound capable of generating Sn—F bonds are the same.

A3. The precursor solution of inventive concept A wherein the organic solvent comprises one or more alcohols.

A4. The precursor solution of inventive concept A wherein the organic solvent comprises 1-propanol, 1-pentanol, 4-methyl-2-pentanol, or combinations thereof.

A5. The precursor solution of inventive concept A having a controlled amount of water.

A6. The precursor solution of inventive concept A having from about 200 ppm to about 10,000 ppm by weight of water.

A7. The precursor solution of inventive concept A having from about 250 ppm to about 1,000 ppm by weight of water.

A8. The precursor solution of inventive concept A wherein R comprises a cyclic alkyl group, an aromatic group, a fluorinated group, an unbranched alkyl group, a branched alkyl group, or a combination thereof.

A9. The precursor solution of inventive concept A wherein R comprises a t-butyl group, an iso-propyl group, or a combination thereof.

A10. The precursor solution of inventive concept A wherein R comprises an alkyl group substituted with I, F, or O atoms.

A11. The precursor solution of inventive concept A wherein the Sn—C bond is radiation sensitive.

A12. The precursor solution of inventive concept A wherein L is an alkoxide, a dialkylamide, an alkylacetylide, an alkylsilylamide, or a combination thereof.

A13. The precursor solution of inventive concept A wherein L is tert-butoxide, sec-butoxide, pentan-3-yloxide, or tert-amyloxide.

A14. The precursor solution of inventive concept A wherein the compound comprises an ammonium fluoride compound represented by the formula NR^{a}R^{b}R^{c}R^{d}F, where R^{a}, R^{b}, R^{c}, and R^{d} are independently hydrogen or an alkyl group having from 1 to 6 carbon atoms or a mixture thereof.

A15. The precursor solution of inventive concept A wherein the compound comprises an ammonium fluoride compound represented by the formula NR′₄F, wherein R′ is hydrogen or an alkyl group having from 1 to 6 carbons.

A16. The precursor solution of inventive concept A wherein the compound comprises NH₄F, N(CH₃)₄F, N(C₄H₉)₄F, or a mixture thereof.

A17. The precursor solution of inventive concept A wherein the molar ratio of Sn to F is from about 100:1 to about 1:1.

A18. The precursor solution of inventive concept A wherein the solution comprises fluorinated organotin species.

A19. The precursor solution of inventive concept A wherein the precursor solution comprises Sn—F bonds.

A20. The precursor solution of inventive concept A wherein the precursor solution comprises fluoride ions.

A21. The precursor solution of inventive concept A wherein the precursor solution comprises a dissolved fluorinated salt complex.

A22. The precursor solution of inventive concept A21 wherein the dissolved fluorinated salt complex is represented by the formula NH₄⁺[RSnL₃F]⁻.

A23. The precursor solution of inventive concept A having a tin concentration from about 0.0025M to about 1 M.

A24. The precursor solution of inventive concept A wherein exposure to EUV radiation is conducted at a dose of no more than about 100 mJ/cm².

A25. The precursor solution of inventive concept A wherein the post-exposure bake is conducted at a temperature of about 50° C. to about 250° C.

B. A photoresist precursor composition comprising a mixture of an organic solvent, one or more organotin compounds represented by the formula RSnL₃, where R is a saturated or unsaturated linear, branched, cyclic, aromatic hydrocarbyl group with 1 to 31 carbon atoms optionally substituted with heteroatoms and L is a hydrolysable ligand, and an ionic fluoride compound represented by the formula NR^{a}R^{b}R^{c}R^{d}F, where R^{a}, R^{b}, R^{c}, and R^{d} are independently hydrogen or an alkyl group having from 1 to 6 carbon atoms or a mixture thereof.

B1. The precursor solution of inventive concept B wherein the organic solvent comprises one or more alcohols.

B2. The precursor solution of inventive concept B wherein the organic solvent comprises 1-propanol, 1-pentanol, 4-methyl-2-pentanol, or combinations thereof.

B3. The precursor solution of inventive concept B having a controlled amount of water.

B4. The precursor solution of inventive concept B wherein the ionic fluoride compound comprises an ammonium fluoride compound represented by the formula NR′₄F, wherein R′ is hydrogen or an alkyl group having from 1 to 6 carbons.

B5. The precursor solution of inventive concept B wherein the ionic fluoride compound comprises NH₄F, N(CH₃)₄F, N(C₄H₉)₄F, or a mixture thereof.

B6. The precursor solution of inventive concept B wherein the molar ratio of Sn to F is from about 100:1 to about 1:1.

B7. The precursor solution of inventive concept B wherein the molar ratio of Sn to F is from about 10:1 to about 1.5:1.

B8. The precursor solution of inventive concept B wherein R comprises a cyclic alkyl group, an aromatic group, a fluorinated group, an unbranched alkyl group, a branched alkyl group, or a combination thereof.

B9. The precursor solution of inventive concept B wherein R comprises a t-butyl group, an iso-propyl group, or a combination thereof.

B10. The precursor solution of inventive concept B wherein R comprises an alkyl group substituted with I, F, or O atoms.

B11. The precursor solution of inventive concept B wherein the Sn—C bond is radiation sensitive.

B12. The precursor solution of inventive concept B wherein L is an alkoxide, a dialkylamide, an alkylacetylide, an alkylsilylamide, or a combination thereof.

B13. The precursor solution of inventive concept B wherein L is tert-butoxide, sec-butoxide, pentan-3-yloxide, or tert-amyloxide.

B14. A radiation-patternable film formed by depositing the photoresist composition of inventive concept B.

C. A method of forming a photoresist solution having Sn—F bonds, the method comprising mixing an organotin precursor represented by the formula RSnL₃ and a fluoride source compound represented by the formula NR^{a}R^{b}R^{c}R^{d}F, where R^{a}, R^{b}, R^{c}, and R^{d} are independently hydrogen or an alkyl group having from 1 to 6 carbon atoms or a mixture thereof in an organic solvent to form the photoresist solution having Sn—F bonds, wherein R is a substituted or unsubstituted hydrocarbyl ligand with 1 to 31 carbon atoms and an Sn—C bond and L is a hydrolysable ligand.

C1. The method of inventive concept C wherein the organic solvent comprises one or more alcohol.

C2. The method of inventive concept C wherein the organic solvent comprises 1-propanol, 1-pentanol, 4-methyl-2-pentanol, or combinations thereof.

C3. The method of inventive concept C wherein the organic solvent is provided as a solvent blend comprising the organic solvent and a controlled amount of water.

C4. The method of inventive concept C3 wherein the solvent blend has from about 200 ppm to about 10,000 ppm by weight of water.

C5. The method of inventive concept C3 wherein the solvent blend has from about 250 ppm to about 1,000 ppm by weight of water.

C6. The method of inventive concept C further comprising adding a controlled amount of water to the photoresist solution.

C7. The method of inventive concept C wherein mixing comprises mixing the fluoride source compound with the organotin precursor to form an initial mixture and mixing the initial mixture with the organic solvent to form the photoresist solution.

C8. The method of inventive concept C wherein mixing comprises mixing the fluoride source compound with the organotin precursor to form an initial mixture, mixing the initial mixture with a first portion of the organic solvent to form a concentrated solution, and mixing the concentrated solution with a remaining portion of the organic solvent to form the photoresist solution.

C9. The method of inventive concept C8 wherein the concentrated solution has a tin concentration of from about 0.25 M to about 2 M.

C10. The method of inventive concept C wherein mixing comprises adding the fluoride source compound to a solution of the organotin precursor in the organic solvent.

C11. The method of inventive concept C wherein the fluoride source compound is first dissolved into a first solvent to form a first solution and the organotin precursor is dissolved in a second solvent to form a second solution, and wherein mixing comprises combining the first solution and the second solution, the organic solvent being a combination of the first solvent and the second solvent.

C12. The method of inventive concept C wherein the organotin precursor and the fluoride source compound are mixed in a molar ratio from about 100:1 to about 1:1.

C13. The method of inventive concept C wherein the organotin precursor and the fluoride source compound are mixed in a molar ratio from about 20:1 to about 1.5:1.

C14. The method of inventive concept C wherein the photoresist solution has a tin concentration of from about 0.0025 M to about 1 M.

C15. The method of inventive concept C wherein R comprises a cyclic alkyl group, an aromatic group, a fluorinated group, an unbranched alkyl group, a branched alkyl group, or a combination thereof.

C16. The method of inventive concept C wherein L is an alkoxide, a dialkylamide, an alkylacetylide, an alkylsilylamide, or a combination thereof.

C17. The method of inventive concept C wherein the fluoride source compound comprises an ammonium fluoride compound represented by the formula NR′₄F, wherein R′ is hydrogen or an alkyl group having from 1 to 6 carbons.

C18. The method of inventive concept C wherein the fluoride source compound comprises NH₄F, N(CH₃)₄F, N(C₄H₉)₄F, or a mixture thereof.

C19. The method of inventive concept C wherein the fluoride source compound comprises an ammonium fluoride compound represented by the formula NR^{a}R^{b}R^{c}R^{d}F, where R^{a}, R^{b}, R^{c}, and R^{d} are independently hydrogen or an alkyl group having from 1 to 6 carbon atoms or a mixture thereof.

D. A structure comprising a substrate and a patterning material on a surface of the substrate wherein the patterning material comprises RSnFₙ moieties where 0<n≤1 and R is a substituted or unsubstituted hydrocarbyl ligand with 1 to 31 carbon atoms and an Sn—C bond.

D1. The structure of inventive concept D wherein the patterning material has an oxo-hydroxo network.

D2. The structure of inventive concept D wherein R has a Sn—C bond.

D3. The structure of inventive concept D wherein R is a substituted or unsubstituted hydrocarbyl ligand with 1 to 31 carbon atoms and an Sn—C bond.

D4. The method of inventive concept D wherein R comprises a cyclic alkyl group, an aromatic group, a fluorinated group, an unbranched alkyl group, a branched alkyl group, or a combination thereof.

D5. The method of inventive concept D wherein R comprises a t-butyl group, an iso-propyl group, or a combination thereof.

D6. The method of inventive concept D wherein R comprises an alkyl group substituted with I, F, or O atoms.

D7. The method of inventive concept D wherein the Sn—C bond is radiation sensitive.

D8. The method of inventive concept D wherein the patterning material has an average thickness on the surface from about 2 nm to about 40 nm.

D9. The method of inventive concept D wherein patterned irradiation of the patterning material forms irradiated regions and non-irradiated regions and wherein the irradiated regions have reduced organic concentration.

D10. The method of inventive concept D9 wherein patterning material at irradiated regions is soluble in aqueous base.

D11. The method of inventive concept D9 wherein patterning material at non-irradiated regions is soluble in organic solvent.

D12. The method of inventive concept D wherein the patterning material comprises ammonium cations.

D13. The method of inventive concept D wherein the patterning material comprises NH₄⁺, N(CH₃)₄⁺, N(C₄H₉)₄⁺, or a mixture thereof.

D14. The method of inventive concept D wherein the substrate comprises a silicon wafer.

D15. The method of inventive concept D9 wherein either the non-irradiated portion of the patterning material is substantially removed to form a negative tone pattern, or the irradiated portion of the patterning material is substantially removed to form a positive tone pattern.

E. A method of patterning an organotin material having Sn—F bonds, the method comprising:
irradiating the organotin material with patterned EUV radiation at a dose corresponding to at least 8% lower than a corresponding dose for the equivalent non-fluorinated organotin patterning material to provide a patterned material with an equivalent critical dimension at the same coating thickness.

E1. The method of inventive concept E wherein the organotin patterning material comprises RSn moieties, wherein R is a substituted or unsubstituted hydrocarbyl ligand with 1 to 31 carbon atoms and an Sn—C bond.

E2. The method of inventive concept E1 wherein the organotin patterning material comprises an oxo-hydroxo network.

E3. The method of inventive concept E1 wherein R comprises a cyclic alkyl group, an aromatic group, a fluorinated group, an unbranched alkyl group, a branched alkyl group, or a combination thereof.

E4. The method of inventive concept E1 wherein R comprises a t-butyl group, an iso-propyl group, or a combination thereof.

E5. The method of inventive concept E1 wherein the Sn—C bond is radiation sensitive.

E6. The method of inventive concept E wherein the ratio of Sn to F atoms is from about 1:0.01 to about 1:0.75.

E7. The method of inventive concept E1 wherein the patterning material has an average thickness on the surface from about 2 nm to about 40 nm.

E8. The method of inventive concept E wherein patterned irradiation of the patterning material forms irradiated regions and non-irradiated regions and wherein the irradiated regions have reduced organic concentration.

E9. The method of inventive concept E wherein the dose is from about 10 mJ/cm² to about 60 mJ/cm².

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to expected uncertainties in the associated values as would be understood in the particular context by a person of ordinary skill in the art.

What is claimed is:

1. A precursor solution for a radiation patterning composition comprising a blend of an organic solvent, an organotin composition represented by the formula RSnL₃, and a compound capable of generating Sn—F bonds wherein R is a substituted or unsubstituted hydrocarbyl ligand with 1 to 31 carbon atoms and an Sn—C bond and L is a hydrolysable ligand.

2. The precursor solution of claim 1 wherein the organic solvent comprises one or more alcohol.

3. The precursor solution of claim 1 wherein the organic solvent comprises 1-propanol, 1-pentanol, 4-methyl-2-pentanol, or combinations thereof.

4. The precursor solution of claim 1 having a controlled amount of water.

5. The precursor solution of claim 1 having from about 200 ppm to about 10,000 ppm by weight of water.

6. The precursor solution of claim 1 having from about 250 ppm to about 1,000 ppm by weight of water.

7. The precursor solution of claim 1 wherein R comprises a cyclic alkyl group, an aromatic group, a fluorinated group, an unbranched alkyl group, a branched alkyl group, or a combination thereof.

8. The precursor solution of claim 1 wherein R comprises a t-butyl group, an iso-propyl group, or a combination thereof.

9. The precursor solution of claim 1 wherein R comprises an alkyl group substituted with I, F, or O atoms.

10. The precursor solution of claim 1 wherein the Sn—C bond is radiation sensitive.

11. The precursor solution of claim 1 wherein L is an alkoxide, a dialkylamide, an alkylacetylide, an alkylsilylamide, or a combination thereof.

12. The precursor solution of claim 1 wherein L is tert-butoxide, sec-butoxide, pentan-3-yloxide, or tert-amyloxide.

13. The precursor solution of claim 1 wherein the compound comprises an ammonium fluoride compound represented by the formula NR^{a}R^{b}R^{c}R^{d}F, where R^{a}, R^{b}, R^{c}, and R^{d} are independently hydrogen or an alkyl group having from 1 to 6 carbon atoms or a mixture thereof.

14. The precursor solution of claim 1 wherein the compound comprises an ammonium fluoride compound represented by the formula NR′₄F, wherein R′ is hydrogen or an alkyl group having from 1 to 6 carbons.

15. The precursor solution of claim 1 wherein the compound comprises NH₄F, N(CH₃)₄F, N(C₄H₉)₄F, or a mixture thereof.

16. The precursor solution of claim 1 wherein the molar ratio of Sn to F is from about 100:1 to about 1:1.

17. The precursor solution of claim 1 wherein the solution comprises fluorinated organotin oxo-hydroxo species.

18. The precursor solution of claim 1 wherein the precursor solution comprises Sn—F bonds.

19. The precursor solution of claim 1 wherein the precursor solution comprises fluoride ions.

20. The precursor solution of claim 1 wherein the precursor solution comprises a dissolved fluorinated salt complex.

21. The precursor solution of claim 20 wherein the dissolved fluorinated salt complex is represented by the formula NH₄⁺[RSnL₃F]⁻.

22. The precursor solution of claim 1 wherein the compound capable of generating Sn—F bonds is capable of generating Sn—F bonds in solution and/or following solvent removal.

23. The precursor solution of claim 22 wherein formation of Sn—F bonds after solvent removal involves thermal or radiation driving force.

24. The precursor solution of claim 1 having a tin concentration from about 0.0025M to about 1 M.
